(19) United States
(12) Patent Application Publication
(10) Pub. No.: US 2004/0174199 A1
(43) Pub. Date: Sep. 9, 2004

(54) Multiplier circuit

(76) Inventor: Martin Simon, Otterfing (DE)

Correspondence Address: Scott B Stahl, Jackson Walker, Suite 600, 2435 North Central Expressway, Richardson, TX, 75080, US

(21) Appl. No.: 10/482,507

(22) PCT Filed: Jul. 3, 2002
(86) PCT No.: PCT/DE02/02427

(30) Foreign Application Priority Data
Jul. 6, 2001 (DE) 10132802.8

(51) Int. Cl. H03K 3/00

(52) U.S. Cl. 327/256

(57) ABSTRACT

A multiplier circuit is specified, for the multiplication of two input signals, in which two transistor pairs (2, 3; 4, 5) couple a first input (1, 2) to an output (9, 10) of the multiplier, load terminals of the transistor pairs (2, 3; 4, 5) being connected to a second input (15, 16) of the multiplier via a current mirror (11, 12). The differential amplifier usually provided in Gilbert multipliers is thereby obviated, with the result that it is possible to achieve improved noise properties of a transmitter arrangement with vector modulator in which the multipliers can preferably be used.

The present invention relates to a multiplier circuit.

Multiplier circuits of analog construction for the multiplication of two input signals, that is to say determination of the sum and difference frequencies thereof, are usually used in transmitters and receivers in radio frequency applications.

A Gilbert multiplier cell constructed using bipolar circuitry is specified in FIG. 10.9 of the document Gray, Meyer: Analysis and Design of Analog Integrated Circuits, John Wiley & Sons, Third Edition 1993, ISBN 0-471-57495-3, wherein a first input signal, for example a local oscillator signal, which has a carrier frequency, is fed to a first input coupled to control inputs of two transistor pairs. The load terminals of the transistors of said transistor pairs are, on the one hand, connected to a current output of the mixer and, on the other hand, are respectively connected in pairs at a common emitter node. A respective load terminal of a differential amplifier is connected to a respective emitter node, the control inputs of which differential amplifier can be fed a second signal to be multiplied, which is usually the input useful signal which is to be converted to a different frequency level or the input useful signal which modulates the carrier frequency. While the differential amplifier operates in its linear range, the transistors of the transistor pairs to which the local oscillator signal can be fed on the control input side are operated in switched fashion and form quadrature modulators of the mixer.

When a Gilbert mixer cell of this type is used in a mobile radio transmitter, two Gilbert cells whose outputs are combined with one another at a summation node are used in order to form a vector modulator to which can be fed, on the input side, an in-phase path and a quadrature path for the transmission of complex-valued baseband signals.

The control inputs of the differential amplifier are accordingly controlled by low-pass-filtered baseband signals, said control inputs being fed by digital/analog converters connected to a digital baseband module on the output side. In order to achieve sufficiently good linearity properties and a sufficiently high gain, a comparatively large operating current has to be set in the differential amplifiers. In addition to the phase noise of the oscillator which provides the local oscillator signal, the comparatively high operating current and the feedback resistors—usually provided—of the differential amplifiers also lead to a comparatively high noise level at the modulator output. In order to satisfy the system requirements of, for example, the mobile radio standard GSM, Global System for Mobile Communication, it is customary to use a surface acoustic wave filter at the output of the modulator.

An analog multiplier circuit is specified in the document EP 1 160 717 A1. The two inputs are designed for feeding in voltage signals. The emitter nodes of the differential amplifiers are connected to one of the inputs via current mirrors. In order to convert the voltage signal into a current signal, a total of four resistors are connected between the current mirrors and ground.

A circuit for setting the amplitude of a signal is specified in the document EP 0 365 085 A2. Of the two coupled differential amplifiers only one is designed for the useful signal amplification of an asymmetrical signal, while the other processes only a DC component of the single-ended signal.

It is an object of the present invention to specify a multiplier circuit which is suitable for use in vector modulators and has improved noise properties with a simple construction.

According to the invention, the object is achieved by means of a multiplier circuit, having the features of the present patent claim 1.

In order to feed a current into the transistor pairs of the multiplier, which comprise transistors which are usually operated in switched fashion, the present invention provides at least one current mirror for feeding in the useful signal to be transmitted. The differential amplifier which is provided in the case of the Gilbert multiplier cell described in the introduction and is driven with the useful signal to be transmitted can thereby be obviated.

Current sources which can be connected to the current mirror on the input side have a significantly higher linearity with a significantly lower supply current in comparison with differential amplifiers. Moreover, the feedback resistors of the differential amplifier can be dispensed with, so that the noise properties of the present mixer circuit are significantly improved.

A further reduction of the noise of the present multiplier circuit may be obtained by reducing the channel width to channel length ratio of the current mirror transistors.

In one preferred embodiment of the present invention, provision is made of a filter circuit for filtering the second input signal that can be fed to the second input of the multiplier circuit, having a current output connected to the input of the at least one current mirror.

In order to avoid undesirable interference effects as a result of mixing higher harmonic frequency components of the useful signal, low-pass filters are usually provided on the input side at frequency mixers or multiplier circuits, said filters usually having a current output anyway on the output side. As a result of this, said current output of the low-pass filters may advantageously be coupled to the inputs of the current mirrors of the multiplier, with the result that it is possible to avoid a conversion of the output current of the filter into a voltage which can then be fed to the conventional Gilbert multiplier cell, the noise properties, the current requirement and also the linearity properties can be improved further as a result of this.

In a further preferred embodiment of the present invention, the filter circuit comprises a low-pass filter.

In the present case, the current source for supplying the second signal input of the mixer, namely the linear input, is preferably the current source that is provided anyway in the output stage of the baseband low-pass filter.

In a further preferred embodiment of the present invention, a voltage-controlled current source is provided, the current output of which is coupled to the input of the at least one current mirror.

The control voltage which can be fed to the voltage-controlled current source represents, for example, a baseband signal that can be fed to the mixer in a mobile radio transmitter. If this signal is present as a voltage signal, it is possible to provide a voltage input with high input resistance at the second input by means of the voltage-controlled current source described, which represents a voltage/current converter with a current mirror connected downstream for forming the second input of the analog multiplier, whilst retaining the improved linearity and noise properties and also the current requirement of the present multiplier circuit.

In a further preferred embodiment of the present invention, the at least one current mirror has an input transistor connected as a diode, a current mirror output transistor being connected downstream of said input transistor. By adapting the channel width to channel length ratios of the current mirror transistors, it is possible to obtain a desired current gain, that is to say a desired translation ratio of the current mirror.

In a further preferred embodiment of the present invention, a low-pass filter is provided between the input and output transistors of the current mirror, which low-pass filter couples the input transistor to the output transistor.

A further reduction of the noise of the present multiplier circuit is obtained by means of a low-pass filter in the current mirror, which is preferably connected between respective control terminals of the current mirror transistors.

In a further preferred embodiment of the present invention, the multiplier circuit is designed to process differential signals.

The subclaims relate to further details and embodiments of the invention.

The invention is explained in more detail below using a plurality of exemplary embodiments with reference to the drawings.

In the figures:

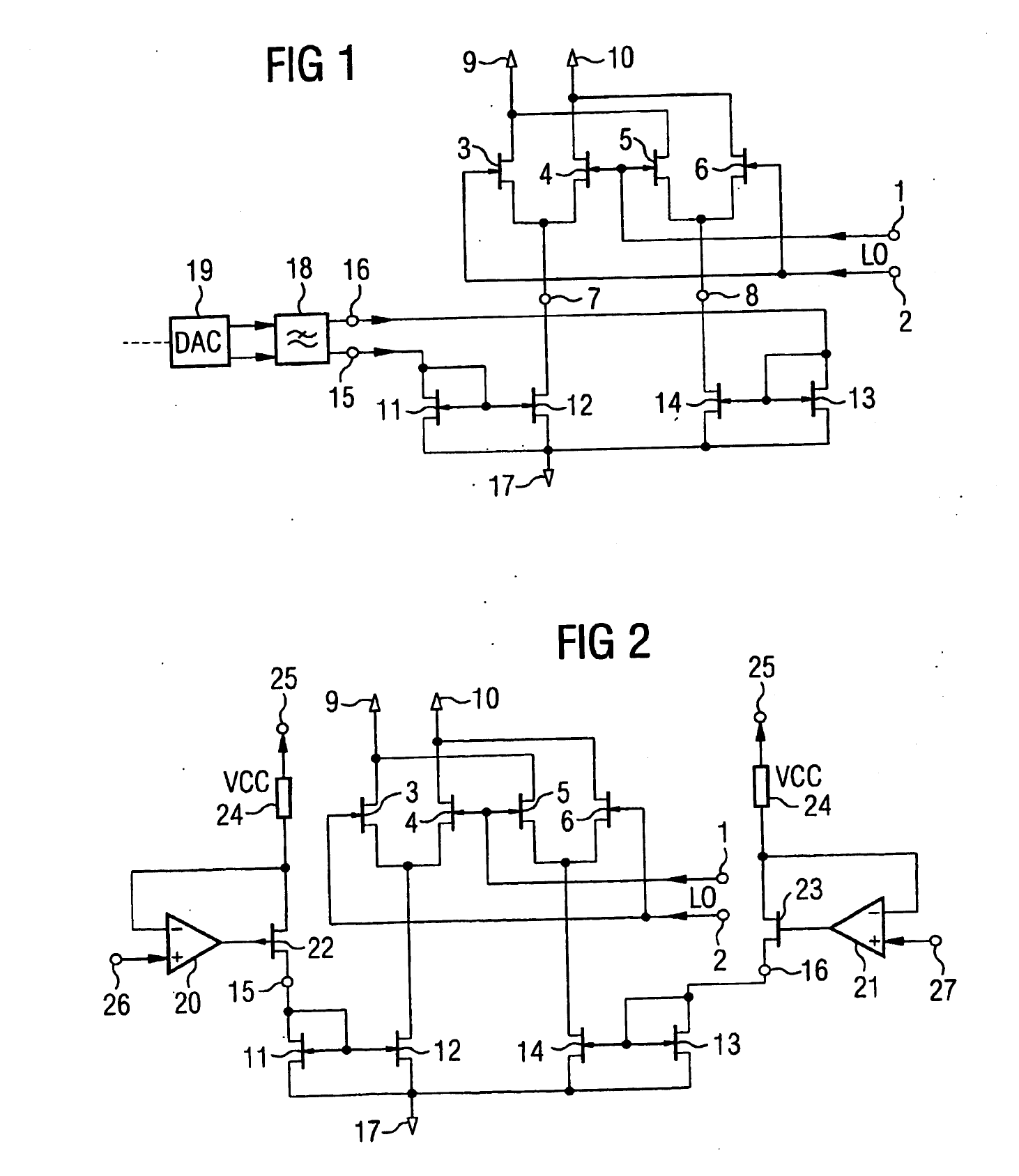

FIG. 1 shows a first exemplary embodiment of the present invention with a low-pass filter as current source,

FIG. 2 shows a second exemplary embodiment of the invention on the basis of a simplified circuit diagram with a voltage-controlled current source,

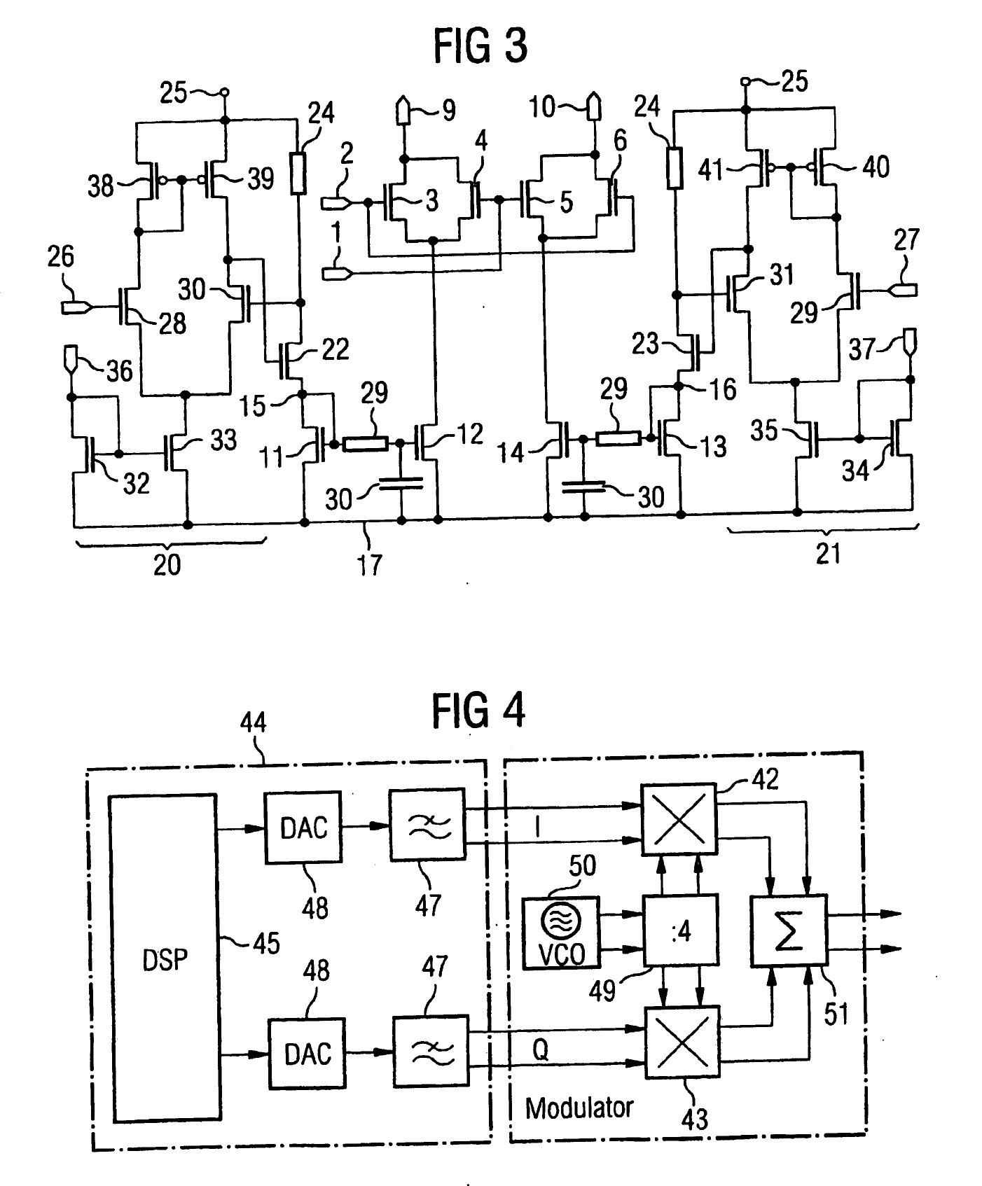

FIG. 3 shows a development of the embodiment in accordance with FIG. 2, and

FIG. 4 shows an application example of the multiplier circuit in accordance with FIGS. 1 to 3 in a modulator of a mobile radio transmitter on the basis of a simplified block diagram.

FIG. 1 shows a multiplier circuit having a first input 1, 2 designed for feeding in a differential signal; a local oscillator signal provided by an oscillator and having a carrier frequency to be modulated can preferably be fed to said first input. The first input 1, 2 is connected to a respective control input of a respective transistor 3, 4, 5, 6, two transistors 3, 4; 5, 6 in each case being connected up to one another in pairs. For this purpose, a respective load terminal of the transistors 3, 4, which form a first transistor pair, and a respective load terminal of the transistors 5, 6, which form a second transistor pair, are connected to one another in order to form a respective current input 7, 8. Furthermore, the controlled paths of the transistors 3 to 6, which are designed as field-effect transistors in the present exemplary embodiment, each have a further load terminal, the further load terminals of the transistors of the transistor pairs being connected up to one another in order to form a radio frequency output 9, 10 of the multiplier circuit. The radio frequency output 9, 10 is designed for providing differential output signals.

The current input 7, 8 of the transistor pairs 3, 4; 5, 6 is connected via a respective current mirror 11, 12; 13, 14 to a second input 15, 16 for feeding in a second input signal to be multiplied. The current mirrors 11, 12; 13, 14 each comprise an input current mirror transistor 11, 13 connected as a diode and also an output transistor 12, 14 connected to the control input of the input current mirror transistor 11, 13 by its control input. The current mirror transistors 11 to 14 are coupled to a reference potential terminal 17 via a respective load terminal.

The output stage of a low-pass filter 18 serves as current source for supplying the current mirrors 11 to 14, which low-pass filter is connected to the second input 15, 16 of the multiplier circuit by its output for carrying differential signals. Connected upstream of the low-pass filter 18 is a digital/analog converter 19, which converts the useful signals to be transmitted, or components of said useful signals to be transmitted, which are usually present as digital signals and which can be fed, for example, from a baseband processing chain, into analog signals. Undesirable spectral components may arise, inter alia, during the digital/analog conversion and can be filtered out prior to a frequency mixing of the useful signal with a local oscillator signal with a carrier frequency by means of low-pass filter 18.

With the current mirror transistors 11 to 14, it is possible to obtain a desired current gain by setting the translation ratio of the current mirrors through suitable setting of the channel width to channel length ratio of the transistors. The transistor pairs 3 to 6, which operate as quadrature modulators in the present exemplary embodiment, are operated in switched fashion.

Since the differential amplifier—usually provided in Gilbert mixers—for feeding in the second input signal can be obviated in the present circuit and be replaced by current sources having significantly higher linearity, the present multiplier circuit operates with a significantly lower current requirement. Moreover, its noise properties are improved.

FIG. 2 shows a further exemplary embodiment of the present multiplier circuit. In this case, at the second input 15, 16 for providing a current source for the current mirror transistors 11 to 14, instead of the low-pass filter 18 provided in accordance with FIG. 1, a respective voltage/current converter formed with an operational amplifier is provided in FIG. 2. The construction of the multiplier circuit between first input 1, 2, second input 15, 16 and output 9, 10 corresponds in terms of connection and function to that already explained for FIG. 1 and, therefore, will not be repeated again at this point. A respective transistor 22, 23 driven by an assigned operational amplifier 20, 21 is connected to the second input 15, 16 by a respective load terminal. A respective further load terminal of the transistors 22, 23 driven by the operational amplifiers 20, 21 is connected to a reference potential terminal 25 via a resistor 24. The resistors 24 operate as a current source and serve in each case for setting the current to be amplified by the current mirrors 11 to 13. By way of example, a symmetrical in-phase signal or a symmetrical quadrature signal in a mobile radio transmitter can be fed in at the non-inverting inputs of the operational amplifiers 20, 21, which form an input for feeding in a differential voltage signal, which input is provided with reference symbols 26, 27. The inverting inputs of the operational amplifiers 20, 21 are in each case connected to that load terminal of the transistor 22, 23 which is connected to the resistor 24, 25, for the purpose of forming a feedback.

With the current sources 24 and the transistors 22, 23 which are driven by the operational amplifiers 20, 21, a voltage-controlled current source, that is to say a voltage/current conversion, is provided which, compared with the voltage inputs with a differential amplifier connected downstream that are provided anyway in Gilbert multipliers, has the advantage that the linearity, noise and current requirement properties of the multiplier are improved.

FIG. 3 shows a development of the multiplier circuit with voltage/current conversion in accordance with FIG. 2 in a realization of the operational amplifiers for voltage/current conversion and the rest of the circuit with MOS field-effect transistors. In this case, apart from the realization using MOS circuitry, the construction and function of the multiplier circuit between first input 1, 2, output 9, 10, transistor pairs 3 to 6, and current input 15, 16 correspond to the exemplary embodiments in accordance with FIGS. 1 and 2 and therefore, will not be repeated again at this point. In the current mirror branches 11 to 14, a development is provided to the effect that an RC element as low-pass filter is in each case interposed between input current mirror transistors 11, 13 and output current mirror transistors 12, 14, with a series resistor 28 and a capacitance 30 connected downstream of the resistor 28 with respect to reference potential terminal 17.

The voltage/current converters with the voltage input 26, 27, the operational amplifiers 20, 21, the current source resistors 24 which are connected to a supply voltage source 25, and the transistors 22, 23 driven by the operational amplifiers 20, 21, correspond in terms of construction and function to the converters already elucidated in FIG. 2 and, therefore, are not explained again at this point. In contrast to FIG. 2, however, FIG. 3 illustrates an embodiment of the operational amplifiers 20, 21 illustrated diagrammatically in FIG. 2 with MOS field-effect transistors. The latter in each case have an input transistor 28, 29 forming the non-inverting input, the control input of which input transistor is in each case connected to the non-inverting input 26, 27 of the operational amplifier 20, 21 and which input transistor is in each case connected by one of its load terminals to the load terminal of a transistor 30, 31 forming the inverting input of the operational amplifier, which transistor, in accordance with FIG. 3, is connected to the node between current source resistor 24 and transistors 22, 23 driven by the operational amplifier. A common load terminal node of the transistors 28, 30; 27, 29 on the reference potential side is connected via a respective current mirror 32, 33; 34, 35 to a respective terminal for feeding in reference current 36, 37. The further load terminals of the operational amplifier input transistors 28, 30; 29, 31 on the supply potential side are connected to one another and to a supply voltage terminal 25 via in each case a further current mirror 38, 39 and 40, 41 respectively.

The additional low-pass filters 29, 30 in the current mirrors 11, 12; 13, 14 advantageously lead to a further improvement of the noise properties of the multiplier circuit.

Finally, FIG. 4 shows the application of a respective multiplier circuit 42, 43 according to the invention in each case in an in-phase branch and a quadrature branch I, Q of a transmission arrangement with complex-valued signal processing.

In this case, the transmission arrangement comprises a baseband module 44, having a block for digital signal processing 45, which provides digital baseband signals to be transmitted in complex-valued fashion, that is to say separated into an in-phase component and a quadrature component I, Q. For the processing of the complex-valued digital signal, a low-pass filter 47 is in each case connected to a respective digital/analog converter 48 provided in the in-phase and quadrature branches I, Q. The low-pass filters 47 are in turn connected by their outputs to the useful signal inputs of the mixers 42, 43. The frequency mixers 42, 43 for the purpose of forming a vector modulator are connected by a respective further input, the local oscillator input, via a common frequency divider 49 to a voltage-controlled oscillator 50, which provides the local oscillator signal. On the output side, the multipliers 42, 43, are combined with a common summation node 51 for the summation of the high-frequency output signals of the multiplier circuits 42, 43, the summation node 51 providing a high-frequency signal to be transmitted for example via an antenna (not depicted).

Since significantly improved noise properties of the multipliers are obtained with the multiplier circuit according to the invention, which dispenses with the differential amplifier of a customary Gilbert cell, the radio frequency signal provided at the summation node 51 on the output side has a particularly large signal-to-noise ratio. Moreover, on account of the reduced current requirement of the multipliers 42, 43 specified, it is possible to achieve a longer battery or accumulator operating period between two charging cycles when using the multipliers in mobile radio transmitters in mobile stations.

1. A multiplier circuit, having
a first input (1, 2) for feeding in a first input signal,
a second input (15, 16) designed for feeding in a second input signal in the form of a current signal,
an output (9, 10) for providing an output signal derived from the first and second input signal,
a first and a second transistor pair (3, 4; 5, 6) having control inputs coupled to the first input (1, 2), and having controlled paths which, on the one hand, are coupled to the output (9, 10) of the multiplier circuit and, on the other hand, form a respective current input (7, 8) and
at least one current mirror (11, 12), which is coupled, on the output side, to a respective current input (7, 8) of a transistor pair (3, 4; 5, 6) and, on the input side, to the second input of the multiplier circuit (15, 16), the multiplier circuit being designed to process differential signals.

2. The multiplier circuit as claimed in claim 1,
characterized in that
provision is made of a filter circuit (18) for filtering the second input signal that can be fed to the second input (15, 16) of the multiplier circuit, having a current output connected to the input of the at least one current mirror (11, 12).

3. The multiplier circuit as claimed in claim 2,
characterized in that
the filter circuit (18) comprises a low-pass filter with a current source on the output side.

4. The multiplier circuit as claimed in claim 1,
characterized in that
a voltage-controlled current source (20, 22) is provided, having a current output coupled to the input of the at least one current mirror (11, 12).

5. The multiplier circuit as claimed in one of claims 1 to 4,
characterized in that
the at least one current mirror (11, 12) has an input transistor (11) connected as a diode, the control terminal of which input transistor is coupled to a control terminal of an output transistor (12) of the current mirror (11, 12).

6. The multiplier circuit as claimed in claim 5,
characterized in that
a low-pass filter (29, 30) is provided, having an input coupled to the input transistor (11) and having an output coupled to the output transistor (12) of the at least one current mirror (11, 12).

7. The multiplier circuit as claimed in either of claims 5 or 6,
characterized in that
the input transistor (11) and the output transistor (12) are directly connected to a reference potential (17) by a respective terminal of their controlled paths.
